(19) United States
(12) Patent Application Publication
(10) Pub. No.: US 2024/0021629 A1
(43) Pub. Date: Jan. 18, 2024

(54) ARRAY SUBSTRATE, METHOD OF MANUFACTURING THE SAME AND METHOD OF IMPROVING PERFORMANCE OF THE SAME, DISPLAY PANEL AND DISPLAY DEVICE

(71) Applicant: BOE TECHNOLOGY GROUP CO., LTD., Beijing (CN)

(72) Inventors: Zheng LIU, Beijing (CN); Meng ZHAO, Beijing (CN); Hongwei TIAN, Beijing (CN)

(73) Assignee: BOE TECHNOLOGY GROUP CO., LTD., Beijing (CN)

(21) Appl. No.: 18/373,767

(22) Filed: Sep. 27, 2023

Related U.S. Application Data
(63) Continuation of application No. 16/462,385, filed on May 20, 2019.

(30) Foreign Application Priority Data
Apr. 27, 2018 (CN) 201810394256.3

(51) Int. Cl. H01L 27/12

(52) U.S. Cl. CPC H01L 27/1251; H01L 27/1218; H01L 27/127

(57) ABSTRACT

An array substrate and manufacturing method and performance improvement method therefor, a display panel, and a display device. The array substrate includes: a substrate base; a shielding layer provided on one surface of the substrate base; a thin film transistor provided on the substrate base and covering the shielding layer; and a compensation layer provided on the side of the thin film transistor away from the substrate base.

### CROSS REFERENCE TO RELATED APPLICATIONS

This application is a continuation application of the U.S. application Ser. No. 16/462,385, which is a U.S. National Phase Entry of International Application No. PCT/CN2018/112065 filed Oct. 26, 2018, which claims the priority of Chinese patent application No. 201810394256.3 entitled “array substrate and method of manufacturing the same, application and method of improving performance of the same” filed to CNIPA on Apr. 27, 2018, the entire text of which is incorporated herein by reference.

### TECHNICAL FIELD

Embodiments of the present disclosure relate to an array substrate, a method of manufacturing the same, a method of improving performance of the same, a display panel, and a display device.

### BACKGROUND

In the manufacturing process of the display panel or array substrate, the bottom shielding metal (BSM) layer is commonly used in the shielding layer, fingerprint identification, or, in the flexible display panel, it is also used to eliminate the effect of moving charges on the side of the flexible substrate. However, due to BSM not being connected with the circuit, the electric field intensity of the additional electric field formed by BSM is uncontrollable. When the additional electric field acts on the active layer, it may cause the abnormal phenomenon of warping in the saturation region of the output characteristic curve, make the output current abnormal, and even affect the threshold voltage of the thin film transistor.

The research on array substrate needs to be deepened.

### SUMMARY

At least one embodiment of the present disclosure provides an array substrate, comprising: a base substrate; a shielding layer provided on a surface of the base substrate; a thin film transistor (TFT) provided on the base substrate and covering the shielding layer; and a compensation layer provided on a side of the thin film transistor away from the base substrate and configured to form a second electric field of an active layer of the thin film transistor.

For example, an orthographic projection of the compensation layer on the base substrate and an orthographic projection of the active layer on the base substrate have an overlapping region.

For example, the thin film transistor has a top-gate structure, and an orthographic projection of an active layer and an orthographic projection of the compensation layer of the thin film transistor on the base substrate have an overlap region, and an orthographic projection of a gate electrode of the thin film transistor on the base substrate does not completely overlap with the overlap region.

For example, the array substrate further comprises a storage capacitor structure, and the storage capacitor structure comprises a first electrode and a second electrode. If the thin film transistor is a bottom-gate structure TFT, the first electrode is arranged on a side of the buffer layer in the bottom-gate structure TFT away from the base substrate; if the thin film transistor is a top-gate structure TFT, the first electrode is arranged on a side of a first gate insulating layer in the top-gate structure TFT away from the base substrate, and the first electrode and a gate electrode of the thin film transistor are formed by a single patterning process; the second electrode is provided on a side of a second gate insulating layer of the thin film transistor away from the base substrate, and the second electrode and the compensation layer are formed by a single patterning process.

For example, the compensation layer is formed by material including a metal or a metal alloy.

For example, the compensation layer has a thickness ranging from about 100 nm to about 500 nm.

Embodiments of the present disclosure also provide a method of manufacturing an array substrate, comprising: providing a base substrate; forming a shielding layer on a surface of the base substrate; forming a thin film transistor (TFT) on the base substrate, the TFT covering the shielding layer; and forming a compensation layer on a side of the thin film transistor away from the base substrate, so as to form a second electric field in the active layer of the TFT.

For example, forming of the thin film transistor comprises: forming a buffer layer on the base substrate, the buffer layer covering the shielding layer; forming the active layer on a side of the buffer layer away from the base substrate; forming the first gate insulating layer on a side of the active layer and the buffer layer away from the base substrate, the first gate insulating layer covering the active layer; forming a gate electrode on a side of the first gate insulating layer away from the base substrate; and forming the second gate insulating layer on a side of the gate electrode and the first gate insulating layer away from the base substrate, the second gate insulating layer covering the gate electrode. An orthographic projection of the active layer and an orthographic projection of the compensation layer on the base substrate have an overlapping region, and an orthographic projection of the gate electrode on the base substrate does not completely overlap with the overlapping region.

For example, forming a storage capacitor structure comprising: forming a first electrode; if the thin film transistor is a bottom-gate structure TFT, the first electrode is formed on a side of the buffer layer of the bottom gate structure TFT away from the base substrate; if the thin film transistor is a top-gate structure TFT, the first electrode is formed on a side of the first gate insulating layer of the top-gate structure TFT away from the base substrate, the first electrode and the gate electrode being formed by a single patterning process; and forming a second electrode on a side of a second gate insulating layer of the thin film transistor away from the base substrate, the second electrode and the compensation layer being formed by a single patterning process.

For example, processes of forming the compensation layer, the shielding layer, and the gate electrode are selected from chemical vapor deposition and physical vapor deposition, respectively.

Embodiments of the present disclosure also provide a display panel comprising the array substrate.

Embodiments of the present disclosure also provide a display panel comprising the array substrate manufactured by the method.

Embodiments of the present disclosure also provide a display device comprising the display panel.

Embodiments of the present disclosure also provide a method of improving performance of the array substrate, comprising: detecting intensity of a first electric field generated by the shielding layer in the active layer of the thin film transistor; and applying a voltage to the compensation layer to allow the compensation layer to form a second electric field in the active layer.

For example, the voltage applied to the compensation layer is about-15V to about 15V.

### BRIEF DESCRIPTION OF THE DRAWINGS

FIG. 1 is a schematically structural diagram of an array substrate in an embodiment of the present disclosure.

FIG. 2 is a schematically structural diagram of an array substrate in another embodiment of the present disclosure.

FIG. 3 is a schematically structural diagram of an array substrate in another embodiment of the present disclosure.

FIG. 4 is a schematically structural diagram of an array substrate in another embodiment of the present disclosure.

FIG. 5 is a flow chart of manufacturing an array substrate in another embodiment of the present disclosure.

FIG. 6 is a schematically structural diagram of an array substrate in yet another embodiment of the present disclosure.

FIG. 7 is a schematically structural diagram of an array substrate in yet another embodiment of the present disclosure.

FIG. 8 is a schematically structural diagram of an array substrate in yet another embodiment of the present disclosure.

FIG. 9 is a schematically structural diagram of an array substrate in yet another embodiment of the present disclosure.

FIG. 10 is a schematically structural diagram of an array substrate in yet another embodiment of the present disclosure.

FIG. 11 is a schematically structural diagram of an array substrate in yet another embodiment of the present disclosure.

FIG. 12 is a flow chart for improving performance of an array substrate in yet another embodiment of the present disclosure.

### DETAILED DESCRIPTION

The technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms, such as ‘first,’ ‘second,’ or the like, which are used in the description and the claims of the present disclosure, are not intended to indicate any sequence, amount or importance, but for distinguishing various components. The terms, such as ‘comprise/comprising,’ ‘include/including,’ or the like are intended to specify that the elements or the objects stated before these terms encompass the elements or the objects and equivalents thereof listed after these terms, but not preclude other elements or objects. The terms, such as “connect/connecting/connected,” “couple/coupling/coupled” or the like, are not limited to a physical connection or mechanical connection, but may include an electrical connection/coupling, directly or indirectly. The terms, ‘on,’ ‘under,’ ‘left,’ ‘right,’ or the like are only used to indicate relative position relationship, and when the absolute position of the object which is described is changed, the relative position relationship may be changed accordingly.

The inventors noticed that in order to reduce the effect of the first electric field generated by the shielding layer on the active layer, an approach of changing the length of the shielding layer or additionally connecting a constant potential to the shielding layer is usually adopted to reduce the effect of the first electric field on the active layer and alleviate the problem of warping of the characteristic curve. However, the above-mentioned solution also may bring some negative effects, for example, affecting the threshold voltage of the device and causing the threshold voltage drift. Moreover, if a constant potential is additionally connected to the shielding layer, the shielding layer needs to be connected in the circuit, but the shielding layer is generally arranged at the lowermost layer of the array substrate (directly arranged on the surface of the base substrate), and holes need to be punched in some insulating layers so that the shielding layer is electrically connected through the viaholes, which increases the process complexity and have poor effect.

The inventors found through research that if a compensation layer is arranged on a side of the thin film transistor away from the shielding layer, a given voltage is applied to the compensation layer to form a second electric field in the active layer, and the electric field distribution of the active layer in the thin film transistor is changed through superposition of the first electric field and the second electric field, adverse effects of the first electric field on the active layer can be relieved or eliminated, and effects of the first electric field on characteristics of the thin film transistor can be compensated. In this way, the abnormal phenomenon of warping in the saturation region of the output characteristic curve can be improved or eliminated, the current can be normally output, while the adverse effect of compensating the change of the threshold voltage of the thin film transistor caused by the first electric field can be improved, as well as the problems of threshold voltage drift and the like can be solved, and the thin film transistor can be restored to a working state without the first electric field affecting the active layer, or even to a better level.

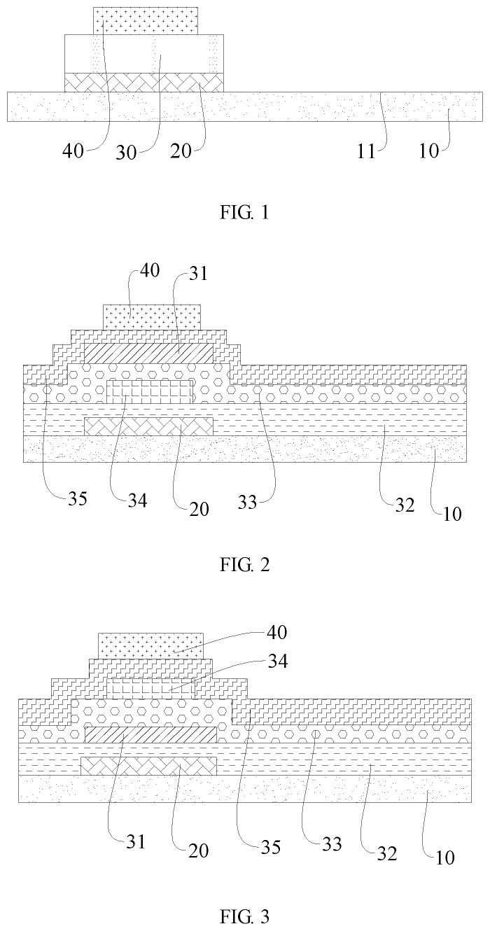

Embodiments of the present disclosure provide an array substrate. According to an embodiment of the present disclosure, referring to FIGS. 1-4, the array substrate includes a base substrate 10; a shielding layer 20 disposed on a surface 11 of the base substrate 10; a thin film transistor (TFT) 30 disposed on the base substrate and covering the shielding layer 20; a compensation layer 40 disposed on a side of the thin film transistor 30 away from the base substrate 10 for forming a second electric field in the active layer of the thin film transistor. The inventors found that by applying a given voltage to the compensation layer 40 to form a second electric field in the active layer in the thin film transistor, and by superposing the second electric field with the first electric field to change the electric field distribution of the active layer in the thin film transistor, the effect of the first electric field on the active layer is further relieved or eliminated, and the effect of the first electric field on the characteristics of the thin film transistor is compensated. In this way, the abnormal phenomenon of warping in the saturation region of the output characteristic curve can be improved or eliminated, and the current can be normally output. At the same time, it can also improve and compensate the adverse effect of the change of the threshold voltage of the thin film transistor caused by the first electric field, solve the problems of threshold voltage drift and the like, and restore the thin film transistor to a working state without the first electric field affecting the active layer, or even to a better level.

It should be noted that the electric field generated by the shielding layer can act on the active layer, and the electric field at the active layer is the first electric field; the electric field generated by the compensation layer can act on the active layer, and the electric field at the active layer is a second electric field, i.e. the compensation layer forms a second electric field in the active layer in the thin film transistor. No restriction is required to the other conductive structure generating the electric field with the compensation layer, and it can be any conductive structure of the array substrate with an overlapping area between its orthographic projections on the base substrate and the orthographic projection of the compensation layer on the base substrate, such as conductive structures, such as data lines, electrodes and the like. It is also possible to arrange a conductive structure at a suitable position in the array substrate so that the orthographic projection of the conductive structure on the base substrate and the orthographic projection of the compensation layer on the base substrate have overlapping areas.

In the following, the effect of the first electric field on the threshold voltage will be described in detail: the existence of the first electric field will cause a slight change in the threshold voltage of the thin film transistor and a drift phenomenon occurs. For example, for a p-type thin film transistor, when the test voltage Vds=−0.1V, the generated first electric field has little effect on the threshold voltage of the thin film transistor, but, when the test voltage Vds=−10.1V, the generated first electric field will cause the threshold voltage of the thin film transistor to drift 0.2V to 0.4V toward the negative direction. For a N-type thin film transistor, its drift direction is opposite to the drift direction of the p-type thin film transistor, and its voltage drift is similar to the voltage drift of the p-type thin film transistor. However, according to embodiments of the present disclosure, the existence of the second electric field can compensate the adverse effect of the change of the threshold voltage of the thin film transistor caused by the first electric field, solve the problems of threshold voltage drift and the like, and restore the thin film transistor to a working state in which the first electric field does not affect the active layer, or even to a better level.

For example, in embodiments of the present disclosure, the types of substrate include, but are not limited to, glass substrate or polymer substrate. If the array substrate is applied to a flexible display panel, the surface 11 of the base substrate may also be provided with a flexible substrate made of an organic thin film, and may also include a barrier layer formed by silicon oxide, silicon nitride, or a stack of them to prevent water oxygen invasion and affect of charges.

For example, in an embodiment of the present disclosure, the material forming the shielding layer includes, but is not limited to, a metal or a metal alloy, such as molybdenum (Mo), aluminum (Al), molybdenum-tungsten (Mo—W) alloy, and the like. In this way, the use performance is high, and the shading effect on the active layer is good. When it is applied to a flexible display panel, the affect of moving charges on the bottom side of the flexible substrate (the flexible substrate is arranged on the side of the base substrate near the compensation layer, and the bottom side refers to the side of the flexible substrate near the base substrate) can also be effectively eliminated.

For example, in embodiments of the present disclosure, the shielding layer may be a single-layer structure or a multilayer structure. In this way, the shading effect is good and the application range is wide.

For example, in embodiments of the present disclosure, the thickness of the shielding layer is about 50 to about 100 nanometers. In this way, the use requirements of the shielding layer and the requirements on the overall thickness of the array substrate can be met.

According to the embodiment of the present disclosure, the structure of the thin film transistor can be any thin film transistor in the art. The following description will be set forth with thin film transistors in bottom-gate structure and top-gate structure as examples.

In some embodiments of the present disclosure, referring to FIG. 2, the structure of the thin film transistor is a bottom-gate structure, for example, a buffer layer 32 covering the shielding layer 20 is provided on a base substrate; a gate electrode 34 is provided on a side of the buffer layer 32 away from the base substrate 10; a first insulating layer 33 covering the gate electrode 34 is provided on a side of the gate electrode 34 and the buffer layer 32 away from the base substrate 10; an active layer 31 is provided on a side of the first insulating layer 33 away from the base substrate 10, and its orthographic projection on the base substrate is covered by an orthographic projection of the shielding layer 20 on the base substrate 10; a second insulating layer 35 covering the active layer 31 is provided on the side of the active layer 31 and the first insulating layer 33 away from the base substrate 10; and a compensation layer 40 is provided on a side of the second insulating layer away from the base substrate 10. In this way, when the shielding layer generates a first electric field acting on the active layer, a given voltage is applied to the compensation layer, and the generated electric field directly acts on the active layer after passing through the second gate insulating layer, that is, the compensation layer can generate a second electric field in the active layer, and the distribution of the electric field in the active layer is changed through the superposition of the first electric field and the second electric field, so that the adverse effect of the first electric field on the active layer is compensated, and the abnormal phenomenon of warping in the saturation region of the output characteristic curve is relieved or eliminated, as well as the current can be output normally, while the adverse effect of the change of the threshold voltage of the thin film transistor caused by the first electric field can be improved and compensated, and the problems of threshold voltage drift and the like can be solved, so that the thin film transistor can be restored to a working state without the effect of the first electric field on the active layer, or even to a better level.

According to the embodiments of the present disclosure, the positional relationship between the compensation layer and the active layer can enable the electric field generated by the compensation layer to act on the active layer. In some embodiments of the present disclosure, in order to facilitate the compensation layer 40 to generate a second electric field in the active layer 31, referring to FIG. 2, the orthographic projection of the compensation layer 40 on the base substrate 10 and the orthographic projection of the active layer 31 on the base substrate 10 can be made to have an overlapping region. In this way, the electric field generated by the compensation layer can act on the active layer more directly, which is convenient to control the magnitude and direction of the second electric field, and the application of a smaller voltage can enable the compensation layer to well form the second electric field with the required intensity in the active layer, so that energy consumption is saved and the electric field generated by the compensation layer can be prevented from being too strong and affecting other circuit structures or components.

In other embodiments of the present disclosure, referring to FIG. 3, the thin film transistor is a top-gate structure, for example, a buffer layer 32 covering the shielding layer 20 is provided on a base substrate; an active layer 31 is provided on a side of the buffer layer 32 away from the base substrate 10, and its orthographic projection on the base substrate is covered by the orthographic projection of the shielding layer 20 on the base substrate 10; a first insulating layer 33 covering the active layer 31 is provided on the side of the active layer 31 and the buffer layer 32 away from the base substrate 10; a gate electrode 34 is provided on a side of the first insulating layer 33 away from the base substrate 10; a second insulating layer 35 covering the gate electrode 34 is provided on the side of the gate electrode 34 and the first insulating layer 33 away from the base substrate 10; a compensation layer 40 is provided on a side of the second insulating layer 35 away from the base substrate and the orthographic projection of the active layer 31 and the compensation layer 40 on the base substrate 10 has an overlapping region, and the orthographic projection of the gate electrode 34 on the base substrate does not completely overlap with the overlapping region. In this way, the orthographic projection of the gate electrode 34 on the base substrate does not completely overlap with the overlapping area, the electric field generated by the compensation layer can be prevented from being completely shielded by the gate electrode, so that a second electric field can be formed in the active layer to realize the effect of compensating the adverse effect of the first electric field on the active layer, the abnormal phenomenon of warping in the saturation area of the output characteristic curve can be alleviated or eliminated, and the current can be normally output.

According to embodiments of the present disclosure, for example, materials forming the gate electrode include, but are not limited to, metals or metal alloys, such as molybdenum, aluminum, molybdenum-tungsten (Mo—W) alloy, and the like. In this way, the use performance is high.

According to the embodiment of the present disclosure, for example, the structure of the gate electrode may be a single-layer structure or a multilayer stacked structure. In this way, the application range is wide and the selectivity is wide.

According to embodiments of the present disclosure, for example, the thickness of the gate electrode may be about 100 nm to about 500 nm, for example, the thickness of the gate electrode may be about 150 nm to about 400 nm. In this way, the use performance is high, and the requirement on the overall thickness of the array substrate can also be met.

According to embodiments of the present disclosure, for example, materials forming the active layer include, but are not limited to, amorphous silicon, poly-silicon, oxide semiconductor, and the like. In this way, the use performance is high, so that the thin film transistor has better and more stable electrical characteristics.

According to embodiments of the present disclosure, for example, the thickness of the active layer is about 10 nm to about 300 nm, for example, the thickness of the active layer is about 50 nm to about 100 nm. In this way, the use requirement for the active layer can be met, and the thinning of the array substrate is facilitated.

According to an embodiment of the present disclosure, for example, the material forming the buffer layer is selected from at least one of silicon oxide or silicon nitride. In this way, the use effect is good and the cost is low.

According to an embodiment of the present disclosure, for example, the thickness of the buffer layer is about 50 to 500 nanometers. In this way, the structure of each layer on the array substrate can be effectively allowed not to affect each other, and the thinning of the array substrate is facilitated.

According to an embodiment of the present disclosure, for example, the material forming the first insulating layer and the second insulating layer may be respectively selected from at least one of silicon oxide or silicon nitride. In this way, the material resource is extensive, the cost is low, and the processing is easy.

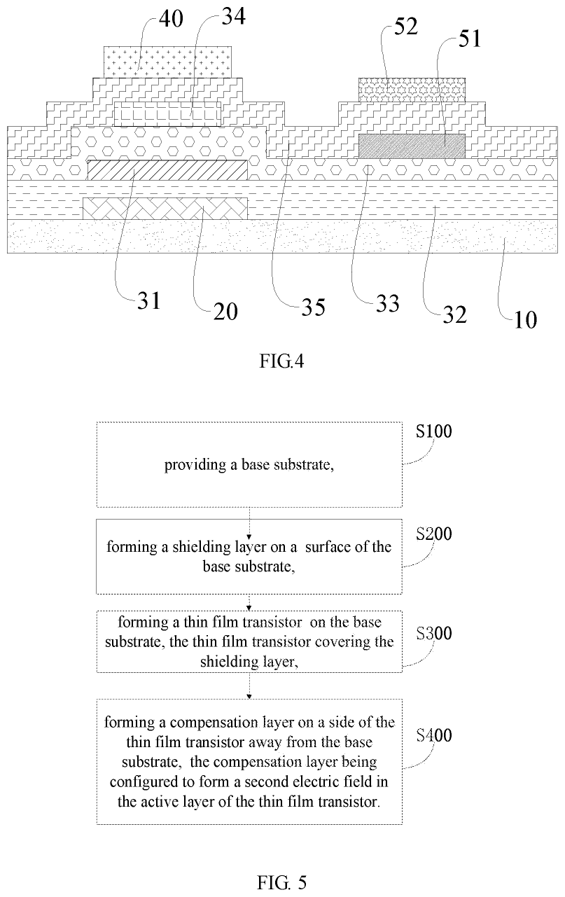

According to an embodiment of the present disclosure, for example, the thickness of the first insulating layer and the second insulating layer may be about 10 to about 200 nanometers, respectively. In some embodiments of the present disclosure, for example, for a thin film transistor with a top-gate structure, in order to facilitate hot electron injection into the active layer, the thickness of the first insulating layer may be designed to be thinner, for example, about 10 to about 40 nanometers; in other embodiments of the present disclosure, referring to FIG. 4, when the array substrate further includes a storage capacitor (the storage capacitor includes a first electrode 51 and a second electrode 52), the thickness of the second insulating layer can be set according to the design requirements of the storage capacitor.

According to the embodiment of the present disclosure, the material forming the compensation layer makes it possible to apply a voltage thereto to generate an electric field. For example, materials forming the compensation layer include, but are not limited to, metals or metal alloys, such as molybdenum, aluminum, Mo—W alloy, and the like. In this way, the use performance is high, the compatibility with thin film transistors is good, and the resources are wide.

According to the embodiment of the present disclosure, for example, the compensation layer may be a single-layer structure or a multilayer stacked structure. In this way, the application range is wide and the selectivity is wide.

According to embodiments of the present disclosure, for example, the thickness of the compensation layer is about 100 nm to about 500 nm, for example, the thickness is about 150 nm to about 400 nm. In this way, the use performance is high, and the design requirement on the overall thickness of the array substrate can be met; and the thinner compensation layer reduces the bulge on the subsequent film layer and reduces the affect of unevenness of the film layer on the subsequent process.

According to the embodiments of the present disclosure, for the magnitude of the voltage applied to the compensation layer, those skilled in the art can design the magnitude of the voltage applied to the compensation layer according to the type of thin film transistor (such as N-type thin film transistor, or P-type thin film transistor), fabrication process and structure (such as the length and width of the channel, the thickness of the insulating layers and the dielectric coefficient of the insulating layer disposed between the compensation layer and the active layer, and the dielectric coefficient of the insulating layer between the shielding layer and the active layer) in the array substrate, or, for example, the intensity of the third electric field after the superposition of the first electric field and the second electric field may be stronger than or weaker than the first electric field, or the intensity of the first electric field may not be changed (i.e., the second electric field is zero), however, embodiments of the present disclosure are not limited thereto. In an embodiment of the present disclosure, the voltage of the compensation layer is about-15V to about 15V. In this way, the compensation layer can generate a second electric field with the required intensity in the active layer, and meet the requirements to the second electric field under various conditions, as well as change the electric field distribution of the active layer in the thin film transistor, so that the effect of the first electric field on the active layer can be alleviated or eliminated, and the effect of the first electric field on the characteristics of the thin film transistor can be compensated. In this way, the abnormal phenomenon of warping in the saturation region of the output characteristic curve can be improved or eliminated, and the current can be normally output, while the adverse effect of the change of the threshold voltage of the thin film transistor caused by the first electric field can also be improved and compensated, and the problems of threshold voltage drift and the like are resolved, so that the thin film transistor can be restored to a working state without the first electric field affecting the active layer, or even to a better level.

According to the embodiment of the present disclosure, as mentioned above, the magnitude of the voltage applied to the compensation layer is related to the thicknesses and dielectric coefficients of the insulating layers provided between the compensation layer and the active layer and between the shielding layer and the active layer. For example, for the thin film transistors of the above two types of structures, the magnitude of the voltage applied to the compensation layer is related to the thicknesses and dielectric coefficients of the first insulating layer, the second insulating layer and the buffer layer. The following description will be set forthwith the thin film transistor in the top-gate structure as an example.

As shown in FIG. 2 to FIG. 4, the electric field generated by the shielding layer needs to pass through the buffer layer to reach the active layer, if the electric field generated by the shielding layer has a certain intensity, with the increase of the thickness of the buffer layer or the increase of the dielectric coefficient of the buffer layer, the intensity of the generated electric field will gradually weaken when it reaches the active layer, i.e. the intensity of the first electric field will weaken. When the intensity of the first electric field in the active layer is constant (other correlation parameters, such as channel length, and width, are also constant), the voltage applied to the compensation layer is mainly designed according to the thickness and dielectric coefficient of the first insulating layer and the second insulating layer. The electric field generated by the compensation layer to which a same voltage is applied needs to pass through the second insulating layer and the first insulating layer before reaching the active layer. With the increase of the thickness of the second insulating layer and the first insulating layer or the increase of the dielectric coefficient, the intensity of the electric field generated by the compensation layer will gradually weaken when it reaches the active layer, that is, the second electric field will weaken. According to the above principle, the voltage of the compensation layer can be designed to generate a second electric field of a desired intensity in the active layer. In this way, the compensation for the adverse effect of the first electric field on the active layer is realized, so that the effect of the first electric field on the active layer can be weakened or eliminated, and the effect of the first electric field on the device characteristics can be compensated, so that the abnormal phenomenon of warping in the saturation region of the output characteristic curve can be eliminated, and the current can be normally output, while the adverse effect of compensating the change of the threshold voltage of the thin film transistor caused by the first electric field can be improved, and the problems of threshold voltage drift and the like can be resolved, so that the thin film transistor can be restored to a working state without the effect of the first electric field on the active layer, or even to a better level.

According to an embodiment of the present disclosure, as described above, the array substrate may further include a storage capacitor structure including a first electrode 51 and a second electrode 52. If that thin film transistor (TFT) is a thin film transistor with a bottom gate structure, referring to FIG. 11, the first electrode 51 is disposed on a side of the buffer layer 32 in the TFT of bottom-gate structure away from the base substrate 10. If the thin film transistor is a TFT of a top-gate structure, referring to FIG. 4, the first electrode 51 is disposed on the side of the first gate insulating layer 33 in the TFT of the top gate structure away from the base substrate, and the first electrode 51 and the gate electrode 34 of the thin film transistor are formed by a same patterning process. The second electrode 52 is disposed on the side of the second gate insulating layer 35 in the thin film transistor away from the base substrate (the bottom-gate structure is shown in FIG. 11 and the top-gate structure is shown in FIG. 4), and the second electrode 52 and the compensation layer 40 are formed by a same patterning process. In this way, the first electrode and the gate electrode are formed by the same patterning process, and the second electrode and the compensation layer are formed by the same patterning process, which can greatly simplify the process and reducing the cost.

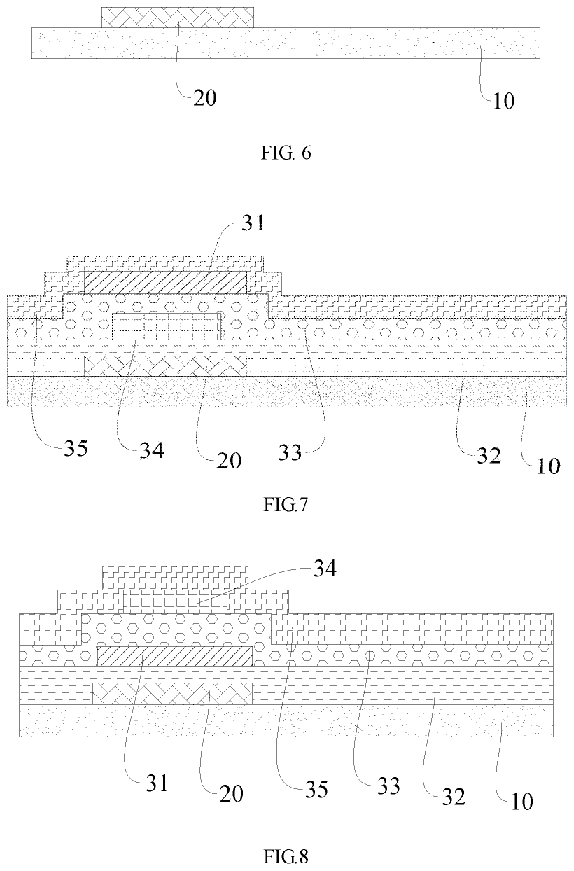

In another aspect of the present disclosure, embodiments of the present disclosure also provide a method of manufacturing an array substrate. According to an embodiment of the present disclosure, referring to FIG. 5, the method includes following operations.
S100: providing a base substrate.
S200: forming a shielding layer 20 on a surface of the base substrate 10, and the schematically structural diagram is shown in FIG. 6.

According to embodiments of the present disclosure, for example, a process of forming the shielding layer includes, but is not limited to, chemical vapor deposition, such as vacuum evaporation; or physical vapor deposition, such as magnetron sputtering. In this way, the operation is simple and the industrial production is easy.
S300: forming a thin film transistor on the base substrate, the thin film transistor covering the shielding layer.

According to embodiments of the present disclosure, for example, the formed thin film transistor may be of a bottom-gate structure type or a top-gate structure type.

In some embodiments of the present disclosure, for example, the thin film transistor is of a bottom-gate structure type. Referring to FIG. 7, for example, the step of forming the thin film transistor includes forming a buffer layer 32 on the base substrate 10, the buffer layer 32 covering the shielding layer 20; forming a gate electrode 34 on the side of the buffer layer 32 away from the base substrate; forming a first gate insulating layer 33 on the side of the gate electrode 34 and the buffer layer 32 away from the base substrate, the first gate insulating layer 33 covering the gate electrode 34; forming an active layer 31 on the side of the first gate insulating layer 33 away from the base substrate, an orthographic projection of the active layer 31 on the base substrate being covered by an orthographic projection of the shielding layer 20 on the base substrate 10; and forming a second gate insulating layer 35 on the side of the active layer 31 and the first gate insulating layer 33 away from the base substrate, the second gate insulating layer 35 covering the active layer 31. In this way, the preparation method is simple and easy for industrial production.

According to some embodiments of the present disclosure, for example, the thin film transistor is a top-gate structure. Referring to FIG. 8, for example, the step of forming the thin film transistor includes forming a buffer layer 32 on the base substrate 10, the buffer layer 32 covering the shielding layer 20; forming an active layer 31 on the side of the buffer layer 32 away from the base substrate, its orthographic projection on the base substrate being covered by the orthographic projection of the shielding layer 20 on the base substrate 10; forming a first gate insulating layer 33 on the side of the active layer 31 and the buffer layer 32 away from the base substrate, the first gate insulating layer 33 covering the active layer 31; forming a gate electrode 34 on a side of the first gate insulating layer 33 away from the base substrate; forming a second gate insulating layer 35 on the side of the gate electrode 34 and the first gate insulating layer 33 away from the base substrate, the second gate insulating layer 35 covering the gate electrode 34. In this way, the preparation method is simple and easy for industrial production.

According to embodiments of the present disclosure, for example, the processes of forming the buffer layer, the first gate insulating layer, the second gate insulating layer, and the gate electrode are respectively selected from chemical vapor deposition (such as plasma enhanced chemical vapor deposition, low pressure chemical vapor deposition, atmospheric pressure chemical vapor deposition, or electron cyclotron resonance plasma chemical vapor deposition), and physical vapor deposition (such as magnetron sputtering), but the embodiments of the present disclosure are not limited thereto.

According to an embodiment of the present disclosure, for example, the method of forming the active layer is illustrated by using poly-silicon as the material for forming the active layer. Amorphous silicon can be formed by a plasma enhanced chemical vapor deposition process or a low pressure chemical vapor deposition process at a deposition temperature below 600 Celsius degrees, and then amorphous silicon is converted into polycrystalline silicon by deposition induced metal, heat treatment crystallization, excimer laser irradiation crystallization or doping impurity activation and other processes to form the active layer. After that, the poly-silicon can be further optimized by heat treatment and dehydrogenation, and then the source and drain regions of the active layer can be ion implanted. For example, for the top-gate structure, the source and drain regions of the active layer can be ion implanted using the gate electrode as a mask to form the source and drain regions. However, embodiments of the present disclosure are not limited thereto.

According to embodiments of the present disclosure, for example, the process of ion implantation includes, but is not limited to, ion implantation with a mass analyzer, ion cloud implantation without a mass analyzer, plasma implantation or solid diffusion implantation, etc. In some embodiments of the present disclosure, for example, the process of ion implantation is ion cloud implantation. For example, a mixed gas containing boron (e.g., B₂H₆/H₂) or phosphorus (e.g., PH₃/H₂) can be used for implantation according to design requirements. The ion implantation energy can be about 10 to about 200 keV, for example, the energy is about 40 to about 100 keV, the implantation dose can be about 1×10¹¹˜ to about 1×10²⁰ atoms/cm³, and the dose is about 1×10¹⁴˜ to about 1×10¹⁸ atoms/cm³. In this way, the formed source and drain electrodes have better performance.
S400: a compensation layer 40 is formed on the side of the thin film transistor 30 away from the base substrate, and is used for forming a second electric field in the active layer of the thin film transistor, its schematically structural diagram is shown in FIG. 1 to FIG. 4.

According to the embodiment of the present disclosure, when the thin film transistor is the bottom gate structure described above, for example, referring to FIG. 2, when the shielding layer 20 generates a first electric field acting on the active layer 31, a given voltage is applied to the compensation layer 40, and the generated electric field directly acts on the active layer 31 after passing through the second gate insulating layer 35, that is, a second electric field is formed in the active layer 31. According to a preferred embodiment of the present disclosure, in order to facilitate the compensation layer to generate a second electric field in the active layer, referring to FIG. 2, the orthographic projection of the compensation layer 40 on the base substrate and the orthographic projection of the active layer 31 on the base substrate can be made to have an overlapping region. In this way, the electric field generated by the compensation layer can act on the active layer more directly, which is convenient to control the size and direction of the second electric field, and a smaller voltage application can enable the compensation layer to well form the second electric field with the required intensity in the active layer, thus energy consumption is saved and the electric field generated by the compensation layer is prevented from being too strong and affecting other circuit structures or components.

According to an embodiment of the present disclosure, when the thin film transistor is the top-gate structure described above, the structure refers to FIG. 3. The orthographic projection of the active layer 31 on the base substrate and the orthographic projection of the compensation layer 40 on the base substrate have an overlapping region, and the orthographic projection of the gate electrode 34 on the base substrate does not completely overlap with the overlapping region. In this way, the electric field generated by the compensation layer can be prevented from being completely shielded by the gate electrode, so that a second electric field can be formed in the active layer to realize the effect of compensating the adverse effect of the first electric field on the active layer, and the abnormal phenomenon of warping in the saturation region of the output characteristic curve can be relieved or eliminated, which enables the current to be normally output.

According to embodiments of the present disclosure, for example, the processes of forming the compensation layer may be selected from chemical vapor deposition (such as plasma enhanced chemical vapor deposition, low pressure chemical vapor deposition, atmospheric pressure chemical vapor deposition or electron cyclotron resonance plasma chemical vapor deposition), and physical vapor deposition (such as magnetron sputtering). In this way, the operation is simple and the industrial production is easy.

The manufacturing method is simple and easy to operate, and is easy for industrial production; moreover, by applying a given voltage to the compensation layer, the compensation layer forms a second electric field in the active layer, and the second electric field changes the electric field distribution of the active layer in the thin film transistor after the second electric field is superposed with the first electric field, so that the effect of the first electric field on the active layer is relieved or eliminated, the effect of the first electric field on the device characteristics is compensated, and the abnormal phenomenon of warping in the saturation region of the output characteristic curve is improved or eliminated, which enables the current to be output normally, while the adverse effect of the change of the threshold voltage of the thin film transistor caused by the first electric field can be improved and compensated, and the problems of threshold voltage drift and the like can be resolved, so that the thin film transistor can be restored to a working state without the effect of the first electric field on the active layer, or even to a better level.

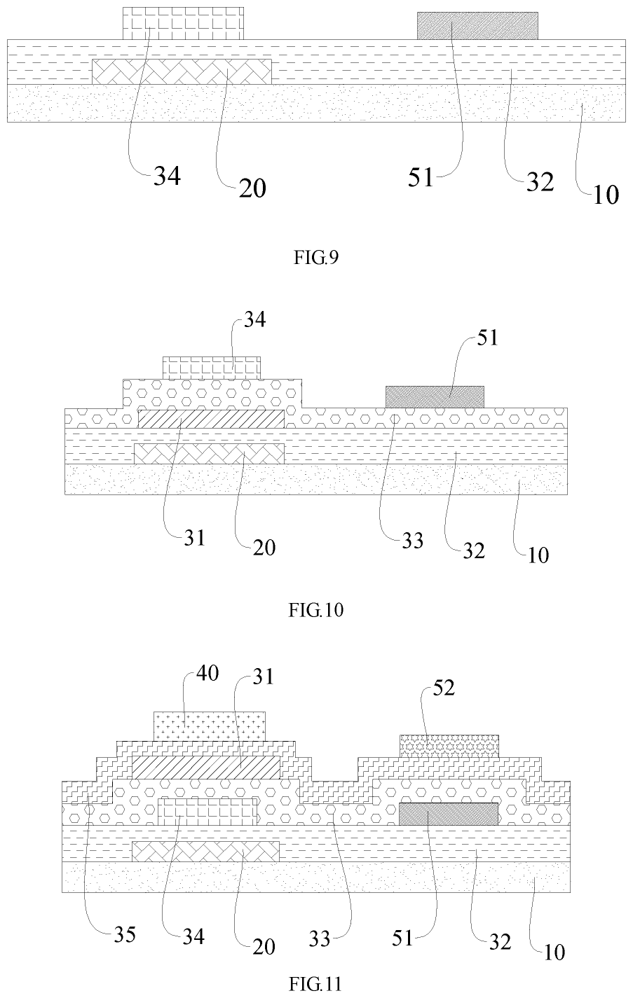

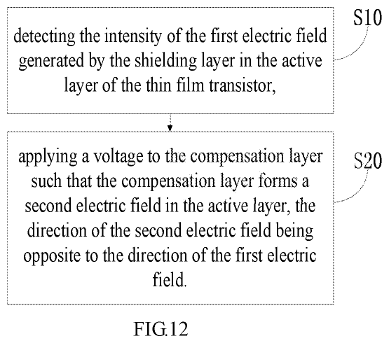

According to an embodiment of the present disclosure, the above method further includes the step of forming a storage capacitor structure, and the step of forming the storage capacitor structure includes forming a first electrode 51. If the thin film transistor is a TFT of a bottom-gate structure, the first electrode 51 is formed on a side of the buffer layer 32 in the TFT of the bottom-gate structure away from the base substrate 10 (see FIG. 9 for a schematically structural diagram); if the thin film transistor is a TFT of a top-gate structure, the first electrode 51 is formed on the side of the first gate insulating layer 33 of the TFT of the top-gate structure away from the base substrate (see FIG. 10 for a schematically structural diagram), and the first electrode 51 and the gate electrode 34 are formed by a single patterning process. A second electrode 52 is formed on a side of the second gate insulating layer 35 of the thin film transistor away from the base substrate (see FIG. 11 for the bottom-gate structure and FIG. 4 for the top-gate structure), and the second electrode and the compensation layer are formed by a single patterning process. In this way, the process flow can be saved, the overall process time can be shortened, the cost can be saved, and the made storage capacitor has better structural performance.

According to the embodiment of the present disclosure, the above manufacturing method of the present application can be used to prepare the array substrate described above. The requirements on the forming materials and thicknesses of the buffer layer, the shielding layer, the first gate insulating layer, the second gate insulating layer, the gate electrode, the active layer, and the compensation layer are the same as those described above, and will not be repeated here.

Embodiments of the present disclosure also provide a display panel. According to an embodiment of the present disclosure, the display panel includes the above-mentioned array substrate or the array substrate prepared by the above-mentioned method. In this way, the display panel has stable electrical characteristics, high service performance, high reliability and long service life. Those skilled in the art can understand that the display panel has all the features and advantages of the above-mentioned array substrate and will not be repeated here.

Those skilled in the art can understand that in addition to the array substrate described above, the display panel also includes structures or components necessary for a conventional display panel, such as structures necessary for a conventional display panel such as a liquid crystal layer, a Color film substrate, sealant, and the like.

Embodiments of the present disclosure also provide a display device. According to an embodiment of the present disclosure, the display device includes the aforementioned display panel. In this way, the display device has stable electrical characteristics, high service performance, high reliability and long service life. Those skilled in the art can understand that the display device has all the features and advantages of the array substrate or display panel described above, and will not be repeated here.

According to an embodiment of the present disclosure, the display device includes, but is not limited to, any electronic device or wearable device having a display function, such as a mobile phone, a television, a tablet computer, a game machine, etc.

Those skilled in the art can understand that in addition to the aforementioned display panel, the display device can also include structures or components necessary for conventional display devices. For example, for a mobile phone, in addition to the aforementioned display panel, the mobile phone also includes structures necessary for a conventional mobile phone, such as a camera module, a voice control module, a fingerprint module, a Central Processor Unit (CPU), etc.

Embodiments of the present disclosure also provide a method for improving the performance of the array substrate described above. According to an embodiment of the present disclosure, referring to FIG. 12, the method includes following operations.
S10: detecting the intensity of the first electric field generated by the shielding layer in the active layer of the thin film transistor;
S20: applying a voltage to the compensation layer to form a second electric field in the active layer.

The inventors found that by forming a second electric field in the active layer, the electric field distribution of the active layer in the thin film transistor is changed, so that the effect of the first electric field on the active layer is relieved or eliminated, and the effect of the first electric field on the characteristics of the thin film transistor is compensated. The abnormal phenomenon of warping in the saturation region of the output characteristic curve is improved or eliminated, and the current can be normally output, while the adverse effect of the change of the threshold voltage of the thin film transistor caused by the first electric field can be improved, the problems of threshold voltage drift and the like are resolved, and the thin film transistor can be restored to a working state without the effect of the first electric field on the active layer, or even to a better level.

According to the embodiments of the present disclosure, there is no restriction to the magnitude of the voltage applied to the compensation layer as long as the second electric field generated by the compensation layer can reduce the adverse effect of the first electric field on the active layer. Those skilled in the art can design the magnitude of the voltage applied to the compensation layer according to the specific types of thin film transistors in the array substrate (e.g., N-type TFT, or P-type TFT), specific preparation processes and structures (e.g., the length and width of the channel, the thicknesses and the dielectric coefficients of the insulating layers arranged between the compensation layer and the active layer and between the shielding layer and the active layer); or, in other words, the magnitude of the third electric field obtained by the superposition of the first electric field and the second electric field is not limited. That is to say, the intensity of the third electric field may be stronger than or weaker than the first electric field, or the intensity of the first electric field may not be changed (i.e., the second electric field is zero), and those skilled in the art may flexibly design according to the above actual processes or the specific structure of the TFT. In the embodiment of the present disclosure, the voltage applied to the compensation layer is −15V to 15V. In this way, the compensation layer can generate a second electric field with the required intensity in the active layer, meet the requirements for the second electric field under various conditions, and change the electric field distribution of the active layer in the thin film transistor, so that the effect of the first electric field on the active layer can be alleviated or eliminated, the effect of the first electric field on the characteristics of the thin film transistor can be compensated, and the abnormal phenomenon of warping in the saturation region of the output characteristic curve can be improved, so as to enable the current to be output normally, while the adverse effect of the change of the threshold voltage of the thin film transistor caused by the first electric field can be improved, the problems of threshold voltage drift and the like can be resolved, and the thin film transistor can be restored to a working state without the first electric field affecting the active layer, or even to a better level.

According to the embodiments of the present disclosure, as mentioned above, the magnitude of the voltage applied to the compensation layer is related to the thicknesses and dielectric coefficients of the insulating layer provided between the compensation layer and the active layer and the insulating layer between the shielding layer and the active layer. For the thin film transistors of the above two types of structures, the magnitude of the voltage applied to the compensation layer is related to the thicknesses and dielectric coefficients of the first insulating layer, the second insulating layer and the buffer layer. The following description will be set forth with the thin film transistor of the top-gate structure as an example:

As shown in FIG. 2 to FIG. 4, the electric field generated by the shielding layer needs to pass through the buffer layer to reach the active layer, if the electric field generated by the shielding layer has a certain intensity, with the increase of the thickness of the buffer layer or the increase of the dielectric coefficient of the buffer layer, the intensity of the generated electric field will gradually weaken when it reaches the active layer, i.e. the intensity of the first electric field will weaken. When the intensity of the first electric field in the active layer is constant (other correlation parameters, such as channel length and width, are also constant), the voltage applied to the compensation layer is mainly designed according to the thicknesses and dielectric coefficients of the first insulating layer and the second insulating layer. The electric field generated by the compensation layer to which a same voltage is applied needs to pass through the second insulating layer and the first insulating layer before it reaches the active layer. With the increase of the thicknesses of the second insulating layer and the first insulating layer, or the increase of the dielectric coefficient, the intensity of the electric field generated by the compensation layer will gradually weaken when it reaches the active layer, that is, the second electric field will weaken. In this way, according to the above principles, those skilled in the art can design the voltage of the compensation layer to generate a second electric field of the required intensity in the active layer. In this way, the compensation for the adverse effect of the first electric field on the active layer is realized, so that the effect of the first electric field on the active layer can be weakened or eliminated, and the effect of the first electric field on the device characteristics can be compensated, so that the abnormal phenomenon of warping in the saturation region of the output characteristic curve can be eliminated, and the current can be normally output, while the adverse effect of the change of the threshold voltage of the thin film transistor caused by the first electric field can be improved, the problems of threshold voltage drift and the like can be resolved, and the thin film transistor can be restored to a working state without the effect of the first electric field on the active layer, or even to a better level.

The following points should be noted:
(1) The accompanying drawings involve only the structure(s) in connection with the embodiment(s) of the present disclosure, and other structure(s) can be referred to common design(s).
(2) Without conflict with each other, features in one embodiment or in different embodiments can be combined.

The above description is only the exemplary embodiments of the present disclosure for explaining the principle of the present disclosure, and the scope of the present disclosure is not limited thereto. A person of ordinary skill in the art can make various changes and modifications without departing from the principle of the present disclosure, and such changes and modifications shall fall into the scope of the present disclosure.

What is claimed is:

1. An array substrate comprising:
a base substrate;
a shielding layer provided on a surface of the base substrate;
a buffer layer provided on the shielding layer;
a thin film transistor (TFT) provided on the buffer layer, the TFT including an active layer, a first gate insulating layer on the active layer, and a gate electrode on the first gate insulating layer, and the TFT covering the shielding layer;
a second gate insulating layer on the gate electrode of the TFT; and
a compensation layer on the second gate insulating layer on a side of the thin film transistor away from the base substrate;
wherein an orthographic projection of the active layer and an orthographic projection of the compensation layer of the thin film transistor on the base substrate have an overlap region, and an orthographic projection of the gate electrode of the thin film transistor on the base substrate falls in the overlap region.

2. The array substrate according to claim 1, wherein a width of the orthographic projection of the compensation layer on the base substrate is larger than a width of the orthographic projection of the gate electrode on the base substrate, and at least one end of the orthographic projection of the active layer on the base substrate is beyond the orthographic projection of the compensation layer on the base substrate.

3. The array substrate according to claim 2, wherein an orthographic projection of the shielding layer on the base substrate is overlapped with the orthographic projection of the active layer on the base substrate.

4. The array substrate according to claim 1, further comprising a storage capacitor structure, wherein the storage capacitor structure comprises a first electrode and a second electrode; the first electrode is arranged on a side of the first gate insulating layer on the active layer of the TFT away from the base substrate, and the first electrode and the gate electrode of the TFT are formed by a single patterning process; the second electrode is provided on a side of the second gate insulating layer on the gate electrode of the TFT and the first electrode away from the base substrate, and the second electrode and the compensation layer are formed by a single patterning process.

5. The array substrate according to claim 1, wherein the compensation layer is formed by material including a metal or a metal alloy.

6. The array substrate according to claim 1, wherein the compensation layer has a thickness ranging from about 100 nm to about 500 nm.

7. A method of manufacturing an array substrate, comprising:
providing a base substrate;
forming a shielding layer on a surface of the base substrate;
forming a buffer layer on the shielding layer;
forming a thin film transistor (TFT) including an active layer on the buffer layer, a first gate insulating layer on the active layer, and a gate electrode on the first insulating layer, and covering the shielding layer;
forming a second gate insulating layer on the gate electrode; and
forming a compensation layer on the second gate insulating layer on a side of the thin film transistor away from the base substrate;
wherein an orthographic projection of the active layer and an orthographic projection of the compensation layer of the thin film transistor on the base substrate have an overlap region, and an orthographic projection of the gate electrode of the thin film transistor on the base substrate falls in the overlap region.

8. The method of claim 7, wherein the buffer layer covers the shielding layer;
the active layer is formed on a side of the buffer layer away from the base substrate;
the first gate insulating layer is formed on a side of the active layer and the buffer layer away from the base substrate, the first gate insulating layer covering the active layer;
the gate electrode is formed on a side of the first gate insulating layer away from the base substrate; and
the second gate insulating layer is formed on a side of the gate electrode and the first gate insulating layer away from the base substrate, and the second gate insulating layer covering the gate electrode, and
wherein a width of the orthographic projection of the compensation layer on the base substrate is larger than a width of the orthographic projection of the gate electrode on the base substrate, and at least one end of the orthographic projection of the active layer on the base substrate is beyond the orthographic projection of the compensation layer on the base substrate.

9. The method according to claim 7, further comprising forming a storage capacitor structure comprising:
forming a first electrode, the first electrode is formed on a side of the first gate insulating layer of the TFT away from the base substrate, the first electrode and the gate electrode being formed by a single patterning process; and
forming a second electrode on a side of the second gate insulating layer of the TFT away from the base substrate, the second electrode and the compensation layer being formed by a single patterning process.

10. The array substrate according to claim 7, wherein an orthographic projection of the shielding layer on the base substrate is overlapped with the orthographic projection of the active layer on the base substrate

11. The method according to claim 7, wherein processes of forming the compensation layer, the shielding layer, and the gate electrode are selected from chemical vapor deposition and physical vapor deposition, respectively.

12. A display panel comprising an array substrate, wherein the array substrate comprises:
a base substrate;
a shielding layer provided on a surface of the base substrate;
a buffer layer provided on the shielding layer;
a thin film transistor (TFT) provided on the buffer layer, the TFT including an active layer, a first gate insulating layer on the active layer, and a gate electrode on the first gate insulating layer, and the TFT covering the shielding layer;
a second gate insulating layer on the gate electrode of the TFT; and
a compensation layer on the second gate insulating layer on a side of the thin film transistor away from the base substrate;
wherein an orthographic projection of the active layer and an orthographic projection of the compensation layer of the thin film transistor on the base substrate have an overlap region, and an orthographic projection of the gate electrode of the thin film transistor on the base substrate falls in the overlap region.

13. A display device comprising the display panel according to claim 12.

14. The array substrate according to claim 1, wherein an electric field formed between the compensation layer and the gate electrode is opposite to an electric field formed between the shielding layer and the active layer.

15. The display panel according to claim 12, wherein an electric field formed between the compensation layer and the gate electrode is opposite to an electric field formed between the shielding layer and the active layer.
